(19) United States
(12) Patent Application Publication
(10) Pub. No.: US 2026/0343824 A1
(43) Pub. Date: Oct. 29, 2026

(54) HOUSING FOR AN ELECTRONIC DEVICE AND METHOD FOR MANUFACTURING THE SAME

(71) Applicant: Inventronics GmbH, München (DE)

(72) Inventors: Peter Sachsenweger, Neutraubling (DE); Federico Rugger, Baierbrunn (DE)

(21) Appl. No.: 19/107,984

(22) PCT Filed: Aug. 29, 2023
(86) PCT No.: PCT/EP2023/073677

§ 371 Date: Feb. 28, 2025

(30) Foreign Application Priority Data
Aug. 29, 2022 (DE) 10 2022 208 951.0

(51) Int. Cl. H05K 7/20; F21V 23/00; H05K 5/04

(52) U.S. Cl. CPC H05K 7/2049; H05K 5/04; F21V 23/007

(57) ABSTRACT

A housing (1) for an electronic device comprises an outer housing part (20), a support member (10) received in the outer housing part (20) and configured to support the electronic device (90), and a spring member (14) disposed between the support member (10) and a lower inner surface of the outer housing part (20) and biasing the support member (10) toward an upper inner surface of the outer housing part (20) opposite to the lower inner surface (23) to press the electronic device (90) supported by the support member (10) against the upper inner surface or a thermally conductive contact member (50) interposed between the electronic device (90) and the upper inner surface. The spring member can be pulled-in or inserted after insertion of the support member and just in such a state the thermally conductive contact member (50), for example provided with a self-adhesive surface, may be compressed between a surface of the electronic device (90) and the inner surface. (FIG. 10)

### TECHNICAL FIELD

Various aspects and embodiments relate to a housing for an electronic device. In particular, they also relate to a housing for an electronic ballast with which semiconductor light sources may be operated.

### BACKGROUND

It is widely known to set up electronic devices such as, in particular, electronic ballasts for operating light sources in housings adapted for use, which offer a certain protection against contact by body parts, or the penetration of dirt, water, and moisture, etc., and also permit a mechanical installation in the surroundings of the respective light sources. Beyond the conventional applications in the home (residential) sector or in offices with power consumptions of, for example, 10-100 W in each case, such devices are also used in the industrial sector and may have power consumptions of, for example, up to 500 W or more there. The requirements, for example, for heat dissipation and fire protection increase hereby and the corresponding housings are dimensioned accordingly and formed with suitable materials. For special applications such as, for example, in larger greenhouses or the like, ballasts with even higher power consumptions come into consideration, without restricting the generality, for example 600 W or 1200 W.

Especially in the example of the use of electronic ballasts for operating light sources in greenhouses-as also in the overall outdoor sector, but frequently also in the indoor sector-a question arises regarding a suitability of electrical operation means for the respective environmental conditions. Hereby, the housing should be configured so as to offer, in particular, protection against a penetration of moisture or water, respectively. The aim is to protect people from hazards or the corresponding circuit parts or the devices operated by them against a failure, for example, due to penetrating water, corrosion or a conductive moisture film. Impairments due to mechanical effects (impacts, etc.) are also to be taken into consideration in order to ensure a reliable function and the safe use of the device.

In order to make it easier for users to select devices suitable for the respective use, so-called IP protection types (IP: ingress protection) were introduced, which are also defined in standards such as DIN EN 60529 or ISO 20653. For the question of moisture, for example, the protection types IP64, IP65, IP66, IP67 and IP68 are relevant. The number “6” mentioned here at the first place denotes the presence of dust-tightness as well as complete protection against contact. The number “4” (i.e., IP64) mentioned at the second place denotes therein protection against spray water from all sides, the number “5” (i.e., IP65) denotes protection against jet water from a nozzle from any angle, the number “6” (i.e., IP66) denotes protection against strong jet water, the number “7” denotes protection against temporary submersion, and the number “8” (i.e., IP68) denotes protection against permanent submersion (as a rule up to 1 m). These protection types IP64 to IP68 consequently indicate, in a graduated manner, approximately the scope of requirements which are to be met for the above-indicated special application sectors (greenhouses, plantations, parks or gardens, outdoor sector, industrial applications, also with indoor sectors, etc.) by the correspondingly configured housings.

This is usually achieved by housings with encapsulations. In such cases, for example, the housing containing a complete electronic assembly is substantially completely filled with a potting compound which is solid or also viscous after curing, so that the electronic components are embedded in this potting compound.

Thermosetting plastics or silicone rubber gels are generally used as potting compound. Epoxy resins, which are also very frequent, also come into consideration. During the potting process, a corresponding electronic assembly is inserted into a prefabricated housing, the openings of which, such as, for instance, for cable bushings, etc.-apart from the filling opening-are already sealed in order to prevent the potting compound from escaping before curing. The still liquid potting compound is then filled into the filling opening.

When potting a housing which has an electronic ballast with electronic components attached to a printed circuit board (for example in SMD design), potting compounds with a low glass transition temperature, such as polyurethane or silicone, are preferably used, because the forces which arise during the shrinking process during the cooling or curing following the filling are in this case lower, which might then act on the components.

However, these advantages during potting are countered by aspects of reduced sustainability, increased costs with regard to the potting material and an increased weight. With regard to the aspect of sustainability, it should be noted that when embedding the components in the potting compound, a reuse of the materials with regard to their separation from one another after the expiry of the service life of the device is problematic. With regard to the costs for the material outlay and the weight, it should be noted that, with suitably adapted housings, the volume occupied by the interior thereof could possibly be reduced, but then standard modules, such as, for instance, continuous casting profiles, which are economical from a view point of costs, can no longer be used, so that an increase in the costs is then to be expected on this side.

Consequently, there is a need for a saving in costs and a reduction in the outlay during assembly. The costs are significantly reduced if the complete potting is dispensed with and the requirements required, for example, according to IP67 are ensured by other cost-effective features.

### Representation of Various Aspects

According to one aspect, a housing for an electronic device is proposed, which comprises an outer housing part. A support member is received in the outer housing part and configured to support or hold the electronic device. In the breadth of the basic concept, this supporting or holding or receiving may consist in a fixed attachment of the electronic device to the support member or also only in a mere, but permanent contact in the assembled state. For this purpose, a spring member is provided being disposed between the support member and a lower inner surface of the outer housing part. The support member is biased by the spring member toward an upper inner surface of the outer housing part opposite to the lower inner surface to press the electronic device (e.g. an assembled circuit board) supported or held by the support member against the upper inner surface or a thermally conductive contact member interposed between the electronic device and the upper inner surface.

Due to the interaction of the spring member and the support member, in this construction the electronic device-generally including a circuit board-is held in a fixed position between the upper inner surface and the support member within the outer housing part, i.e., is sandwiched. The terms “lower” and “upper” used here with respect to the inner surface of the outer housing part are to be understood purely subjectively and are not necessarily to be interpreted here in a limiting manner with respect to the direction of gravity or the opposite direction thereof, especially since the housing may generally be installed with respect to gravity in various orientations at the site of use, e.g., in greenhouses, industrial halls and/or fairs, passages, large offices, etc. Instead of “lower inner surface”, the term “first inner surface” could also be used in the same manner, and accordingly instead of “upper inner surface”, the term “second inner surface” could also be used in the same manner, without restricting the scope of use. Rather, the term merely serves to distinguish between any two opposite inner surfaces. The two inner surfaces also need not necessarily be planar but may themselves be structured for various purposes (stiffening of the component, mechanical attachment structures).

The proposed construction enables a stable, safe and permanent positioning of the electronic device in the interior space of the outer housing part. The spring member may even partially damp vibrations and compensate for mechanical tolerances. By pressing against the inner surface of the outer housing part with correspondingly close contact, it is possible to efficiently dissipate the heat generated in the electronic device to the outer housing part via thermally conductive members of the device itself and via a specially inserted thermally conductive contact member, such as a thermal pad, for example.

However, a particular advantage results from the fact that the use and implementation of a potting compound can become superfluous by the proposed measures if the stability of the mounting of the electronic device and the sufficient heat dissipation in the housing is ensured. It has been calculated that 20% or more of the manufacturing costs can be saved and the total weight of the apparatus containing the housing and the electronic device can be significantly reduced by more than 30%. In such cases, it is to be taken into consideration that, in addition to the pure material costs, several working steps are also dispensed with during production: A) in each case the alignment of the outer housing part along two axes before filling, B) the filling process itself, and C) the subsequent curing of the potting compound. This also leads to a saving of time during production. Furthermore, according to specific embodiments, in applications in the industrial sector and furthermore also, for example, in greenhouses, etc. also advantages arise to the effect that, in the case of a total weight that is usually present here in a single-digit or double-digit range of kilograms, the load-bearing capacity of the constructions, for example at the rails or supports in the ceiling region, on which the components are to be attached, is relieved. In the specific embodiment of greenhouses, these constructions may also be steel profile frameworks with defined load limits. At the same time, the field of application is also extended by the material and weight savings. Furthermore, a reduction of the total combustible mass may also constitute a particular advantage.

A further, particularly noteworthy advantage consists in that, after the expiry of the service life of the electronic device in question, the outlay for recycling and the amount of no longer usable material and the costs for disposal are significantly reduced. The sustainability is thus decisively improved. At the same time, customary and in this respect harmless materials such as steel and/or plastics can be used for the additional elements here, namely the spring element and the support element. Electronic components provided with hazardous materials such as arsenic can thus be very easily identified and individually treated without silicone adhesions, for example, remaining thereon.

The support member may be any element which absorbs the clamping force of the spring element and transmits it to the electronic device. In the simplest case, for example, this may be a mere frame which allows the electronic device to be guided within the outer housing part away from the lower inner surface toward the upper inner surface. According to a specific development which is described below, however, the support member may also be a trough-like element. According to a specific embodiment, it is therefore advantageous if the support member is at least partially in sliding contact with lateral inner surfaces of the outer housing part which, for example, connect the upper and lower inner surfaces to one another. For this purpose, the support member may have lateral spacers with the ability to slide on the lateral inner surfaces. Preferably, the support member and the spacers are dimensioned such that, in the assembled state, a slight clearance with respect to the lateral inner surfaces of the outer housing part can still remain.

According to a particular aspect of the invention, the outer housing part of the housing may comprise a hollow tube profile having two tube openings opposite to each other and may comprise the said opposite inner surfaces. The spring member can thereby be slidably inserted in a simple manner during assembly of the housing or the entire electronic device at the lower inner surface through one of the two tube openings to its predetermined spatial position “below” the support member or may pulled into the interior space from the corresponding opposite tube opening.

According to an embodiment of the aspect, the support member may have a lower side facing the lower inner surface. At least on the lower side, spacers may be configured at predetermined positions. In a state in which the spring member is not yet inserted during assembly of the housing, said spacers contact the lower inner surface of the outer housing part in order to allow sliding insertion of the support member into the tube profile during assembly due to the smaller contact surface, but not only that, but also to allow sliding insertion of the spring member therebelow, since the spacers create a free space here due to the elevated position of the support member.

According to one embodiment, the outer housing part comprises, in addition to the hollow tube profile, also two end plates opposite to each other and attachable at the end faces to the two tube openings. The assembly is thus easily carried out and standard components which are simply cut to size and are economically available from a market point of view can be used.

This applies in particular if, according to a specific embodiment, an extrusion or continuous casting profile, in particular made of aluminum, is used for the hollow tube profile. Optionally, the hollow tube profile may also have a substantially rectangular cross-section, into which the support member and the spring member can be inserted along its longitudinal axis. The outer surface of the tube profile may have a structure (corrugation, etc.) for better cooling.

Furthermore, the outer housing part may have one or more flanges for fastening to an external structure (wall of a building, framework of a greenhouse, etc.). According to a specific embodiment, a holder extending in the longitudinal direction may also be provided on the outside of the tube profile, which holder is plugged onto or pushed onto a corresponding holder on the framework or the wall with a complementary cross-sectional profile, for example a T-shape.

Furthermore, at least one of the end plates (possibly also both) may optionally have in addition sealing cable bushings for the electrical cables of the electronic device. Due to the preferable omission of encapsulation via a potting compound, increased requirements may exist in the present case for the tightness of the outer housing part, which is why the seals may be designed to be reinforced or improved in comparison with the prior art. Due to this structure with moisture protection, the more demanding protection types IP67 or even IP68 may preferably be achieved. However, the protection types IP65 and IP66 are likewise preferred.

According to a further embodiment, the support member has a flat trough-like construction with side walls, wherein, as mentioned, the side walls may also have spacers which are configured to contact corresponding lateral inner surfaces of the tubular profile in the installed state. Due to the trough-shaped construction, the electronic device may be received in a mechanically safe and stable manner and the degree of guidance in the direction of the spring force may be improved.

Further developments of various aspects relate to the spring member. The spring member may, for example, comprise a number of spring clips which each extend towards the lower inner surface of the outer housing part when the spring member is installed or inserted, respectively. The spring clips contact the lower inner surface and, taken together, exert a pressure force distributed over the underside of the support member on the support member towards the upper inner surface. The uniform and distributed exertion of pressure further improves a safe guidance of the support member with the electronic device disposed thereon.

An embodiment of this aspect provides that the spring member comprises a metal plate, preferably made of steel or another metal that is flexible over product life, wherein the metal plate abuts against the underside of the support member. A number of spring clips is cut out from the metal plate. This represents a form for the spring member that is particularly easy to produce. The spring clips may then each be bent towards one side of the metal plate out of a plane of the metal plate, wherein this side may face the lower inner surface of the outer housing part in the inserted state of the spring member. In other respects, such a spring member may be adapted in such a way that the metal plate contacts the lower inner surface and the spring clips are bent out in the direction of the underside of the support member and correspondingly transmit the clamping force to the support member via contact points. According to an embodiment, the spring clips may also be bent away from the metal plate in both directions, for example in an alternating manner.

Furthermore, according to a refinement of the embodiment, the spring clips may be cut out from the metal plate in such a pattern that they have a free end, wherein the spring clips extend substantially parallel to each other and the free end each points in the same direction, wherein the direction points parallel to a longitudinal axis L of the housing which extends through both tube openings. The free ends may form those contact points with the lower inner surface of the outer housing part or the underside of the support member, respectively.

According to a specific embodiment, two or more of the metal plates are provided with the spring clips each. When the spacers are arranged on the underside of the support member in at least two rows and they extend parallel to each other and to the longitudinal axis L of the housing, the metal plates may be dimensioned such that they can be inserted between the rows of spacers. In doing so, they then exert the pressure force upwards, so that the electronic device is pressed against the upper inner surface and thus fixed. The spacers of the support member no longer need to touch the lower inner surface in the assembled state because the spring element pushes the support member away from the lower inner surface in this state.

In this and other embodiments, a further advantage becomes particularly apparent: namely, when a thermally conductive contact member is provided and it has an adhesive surface/self-adhesive surface for positioning on components of the printed circuit board. This may preferably be a thermal pad which is provided with a self-adhesive surface on at least one side, preferably both sides. In this way, the thermal pad is fixed to the upper inner surface of the outer housing part and to an at least partially planar and thermally conductive member of the electronic device, then, by laterally inserting the support member with the electronic device disposed thereon in a first step and subsequently lifting the support member with pressing the electronic device in a second step, adhesion of the thermal pads or of a comparable adhesive layer also serving for fixing to the upper inner surface in a not yet completely inserted state is avoided. The process of assembly is consequently even enabled with this concept, or is at least further improved or simplified, respectively.

The inner surface (e.g. metal surface of the continuous casting profile) may be connected to thermally conductive members of the electronic device directly or indirectly via thermally conductive thermal pads, pastes or adhesives, or via additional metal members, in particular plates and/or screws, to dissipate the heat. In this case, the heat is transmitted from the inside—it is generated in the electronic components on the printed circuit board—e.g., to the thermal pads and/or to the thermally conductive paste (thermal grease) on the outer housing part.

As described above, one aspect of the invention provides for keeping an interior space formed by the outer housing part free of potting compound otherwise filled into the interior space, in particular free of silicone, epoxy resin or tar.

Another aspect provides that the housing also comprises the electronic device. The combination of housing and electronic device thus together forms an electronic apparatus, wherein the electronic device comprises a printed circuit board with electronic components attached thereto. The electronic device may preferably be an electronic ballast for semiconductor light sources. Furthermore, in the case of such an apparatus, a power consumption of 500 watts or more is advantageous in the present case and is therefore preferred. Apparent advantages may even be seen in the case of lower power consumption.

According to a refined embodiment, a passage channel opening to the outside may be formed in one of the end plates at the end faces of the outer housing part. A valve for pressure compensation and the possibility of removing air moisture from the interior of the assembly is provided in the passage channel, which valve is permeable to air in both directions, but is permeable to moisture only in one direction to the outside.

Two functions are fulfilled by the valve: the valve acts, on the one hand, by a membrane in order to reduce the overpressure in the interior space (i.e., a pressure compensation with the surroundings), when the electronic assembly heats up during operation, and, on the other hand, by the same or an additional membrane, in that the accumulation of moisture in the interior is prevented by the resulting underpressure, when the electronic assembly cools in the interior. Otherwise, moisture possibly accumulating in the interior space of the outer housing part could lead to a loss of function and safety of the printed circuit board and of the installed electronic components.

An advantageous method corresponding to the described design may be found in the accompanying, coordinated method claim.

Further advantages, features and details of the various aspects result from the claims, the following description of preferred embodiments and with reference to the drawings. In the figures, identical reference signs denote identical features and functions.

### BRIEF DESCRIPTION OF THE DRAWINGS

In the figures:

FIG. 1 shows a perspective representation of a support element of a proposed housing according to an embodiment;

FIG. 2 shows a partial perspective representation of the process of placing an electronic device in the first inner housing part in FIG. 1;

FIG. 3 shows a perspective representation of the state after completion of the placement in FIG. 2; and the mounting direction to the tubular profile.

FIG. 4 shows a perspective representation of the mounting state in FIG. 3.

FIG. 5 shows a perspective representation of the cross-section in the longitudinal direction of FIG. 4. A contact between the underside of the support element and the inside of the tubular profile is visible;

FIG. 6 shows a perspective representation of the mounting of the spring element;

FIG. 7 shows a representation of the mounted end plate;

FIG. 8 shows the mounted end plate of FIG. 7;

FIG. 9 shows a perspective representation of the mounted assembly including the spring element in actuation and detail of the pressure compensation valve;

FIG. 10 as FIG. 9, however, in a section through cable bushing.

### PREFERRED EMBODIMENT(S) OF THE INVENTION

In the following description of preferred embodiments, it is to be taken into consideration that the present disclosure of the various aspects is not restricted to the details of the construction and the arrangement of the components as represented in the following description and in the figures. The embodiments can be put into practice or carried out in various ways. Furthermore, it is to be taken into consideration that the phraseology and terminology used herein is used only for the purpose of the specific description and should not be construed by a person skilled in the art as such in a limiting manner. Furthermore, in the following description, identical reference signs in the various embodiments or figures denote identical or similar features or objects, so that in some cases a repeated detailed description thereof is dispensed with in order to preserve the compactness and clarity of the representation.

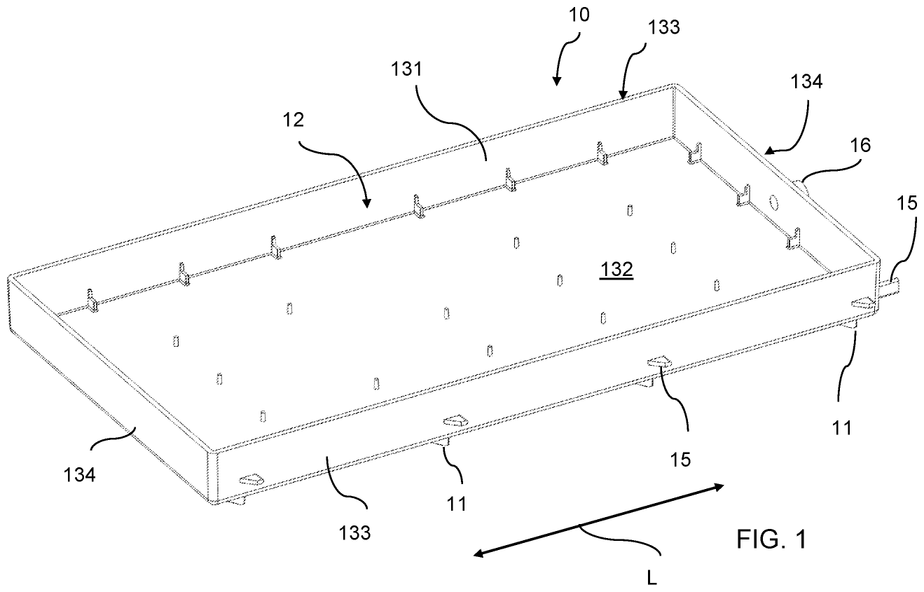

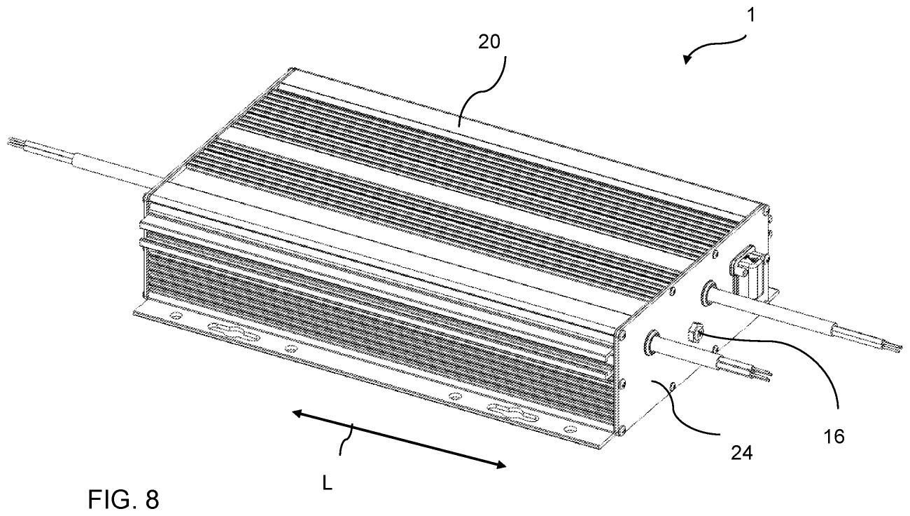

FIGS. 8-10 show a preferred embodiment of a housing 1 in various perspectives and sections, while for clarification, FIGS. 1-7 reflect individual parts and steps of the assembly of the housing 1 starting from the provision of a support element 10 for an electronic device (e.g., an electronic ballast). For the sake of understanding of the individual components, a description of the assembly is made first in the following.

FIG. 1 shows an initially provided support element 10 in a perspective view, wherein the support element 10 has a flat trough-like or cuboid-like construction with a rectangular base 132 and four upright side walls 133, 134 standing perpendicularly or parallel to each other, respectively. The side walls 133 extend parallel to a longitudinal axis L and the end side walls 134 extend substantially perpendicularly to the longitudinal axis L. The side walls 133, 134 have a substantially corresponding height and form an edge on the side facing away from the base 132, through which an opening 131 in the cuboid shape is formed. The opening also remains open in the finally assembled state.

An interior space 12 is formed by the base 132 and the four side walls 133, 134, in which interior space-as indicated in FIG. 1 without reference signs-e.g., at the transition points between the walls, reinforcing structures or filigree support structures distributed on the surface of the base 132 can be disposed for supporting the printed circuit board 95 to be inserted later.

Furthermore, projections serving as spacers 15 are disposed at regular intervals from each other on the outer surfaces of the side walls 133 and at least the one end side wall 134. Furthermore, flat triangular spacers 11 also extend downwardly from the outside of the base 132, i.e., from an underside of the support member. The support member 10 shown in FIG. 1 can be produced in one piece, for example, by injection molding, from a plastic or a resin.

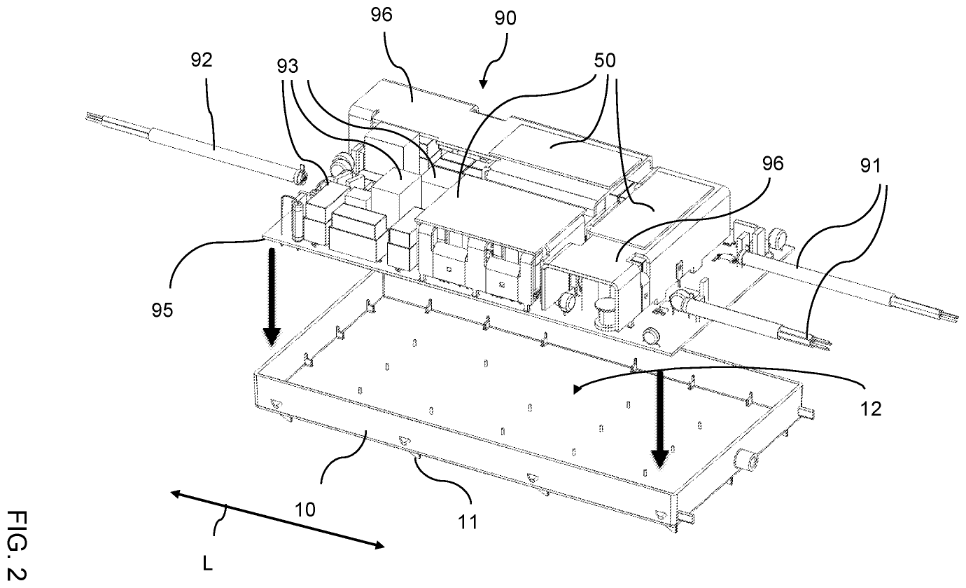

FIG. 2 shows at least one step of inserting an electronic device 90 from above into the interior space 12 of the support member 10 shown in FIG. 1. The electronic device 90 may be an electronic ballast for operating lights, for example, with semiconductor light sources (LEDs). Such electronic ballasts are widely known in the technical field, so that reference can be made to relevant literature at this point with regard to the components. In the example, the electronic ballast is designed for a power of, for example, 600 W or 1200 W. The electronic device 90 comprises a printed circuit board 95 on which the electronic components (e.g., capacitors, resistors, integrated circuits having transistors, etc.) are disposed and interconnected in a known manner.

FIG. 2 shows, purely by way of example, two electrical cables 91, which correspondingly form outgoing line strands for supplying the lighting means, usually LEDs (not shown), with current and with open-loop and closed-loop control elements. In this embodiment, the cables 91 extend along the longitudinal axis L and have a height above the base 132 in the installed state, so that they extend beyond the end side surface 134. The electronic device 90 is also connected to the opposite end face of the support member 10 via an electrical cable 92, which herein serves to supply power, for example, with mains voltage. The reference sign 93 denotes, purely by way of example, some of the electronic components, which together result in the circuit design of the electronic device.

As can likewise be found in FIG. 2, individual electronic components 93 of the electronic device 90 are provided with thermally conductive metal surfaces 96 above the interior space 12 of the support member 10 (in the installed state). These metal surfaces 96 at the same time form contact surfaces for thermally conductive thermal pads 50, which adhere to the metal surfaces 96 by means of thermal grease. In this way, heat can be dissipated from the electronic device 90 during operation.

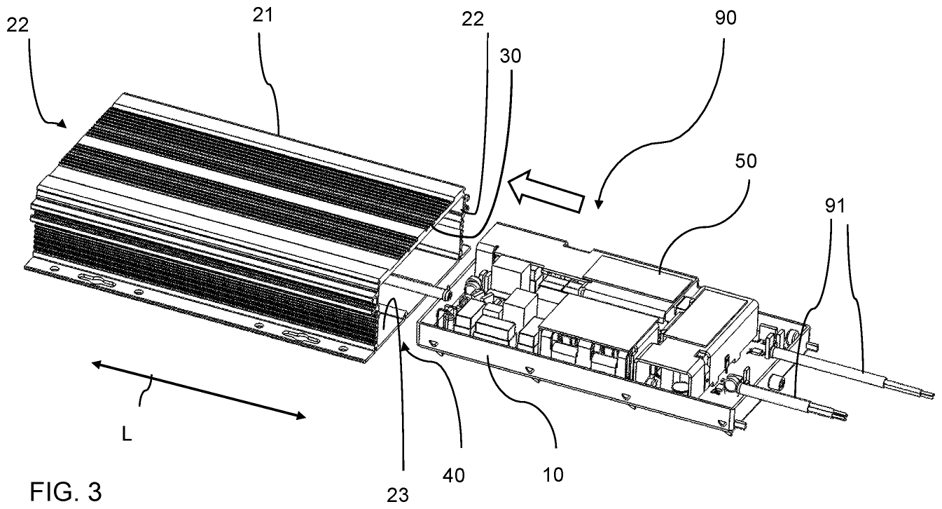

FIG. 3 shows the process of inserting the support member 10 assembled with the electronic device 90 into a tube profile 21 of an outer housing part 20 according to the embodiment. The tube profile 21 is formed, for example, as an extruded continuous casting profile made of aluminum, which has been cut to a suitable length in order to receive the inner housing part 10. This cut, as in the case of running meter goods, considerably reduces the production costs. As shown in FIG. 3, the support member 10 is inserted along its longitudinal or transverse axis L into one of the two tube openings 22 of the tube profile 21 and then completely inserted into the tube profile 21. The position of the support member 10 within the tube profile 21 is defined by the lateral spacers 15. In the upright state shown, the support member 10 rests with its lower spacers 11 on a lower inner surface 23 of the tube profile 21 due to its weight. In other words, the height of the spacers 11 or the total height of the construction of support member 10, electronic device 90 and thermal pad 50 is not sufficient to establish contact with the upper inner surface of the tube profile 21. The thermal pads 50 thus do not (yet) touch an opposite upper inner surface 30 during the insertion. Since the upper surface of the thermal pads 50 is generally likewise self-adhesive, the remaining distance between the thermal pads 50 and the upper inner surface 30 thus supports a smoothly sliding, resistance-free insertion of the construction of support member 10, electronic device 90 and thermal pad 50 (wall contact only via the spacers 11 and 15 if applicable). In the embodiment, the cables 92 and 91 are mounted on the electronic device 90 before the insertion; however, they may also be connected to the electronic device 90 subsequently if applicable. Furthermore, insertion through the opposite tube opening 22 is also possible.

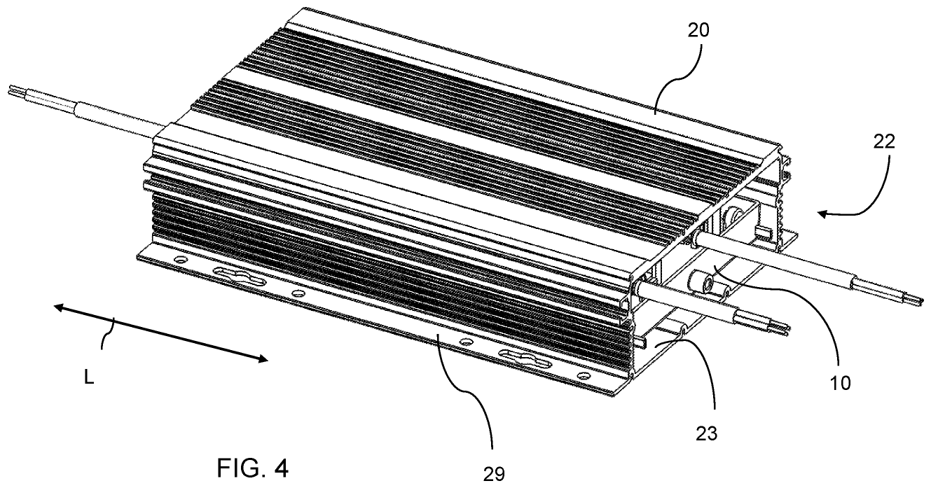

FIG. 4 shows the state reached after the insertion.

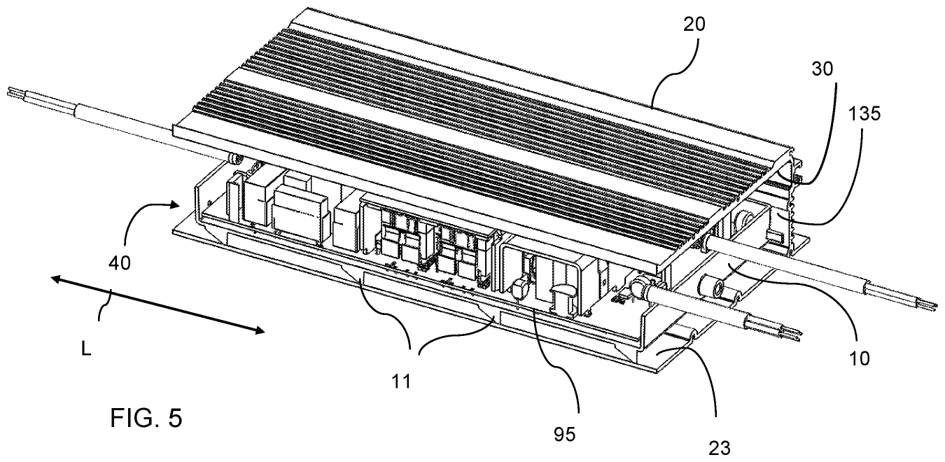

FIG. 5 shows a section through the housing 1 assembled to this extent along the longitudinal axis L. It can be seen that the spacers 11 of the support member 10 contact the lower inner surface 23 of the tube profile 21. There is still no contact between the thermal pads 50 and the upper inner surface 30 of the tube profile 21, i.e., a free space or distance remains.

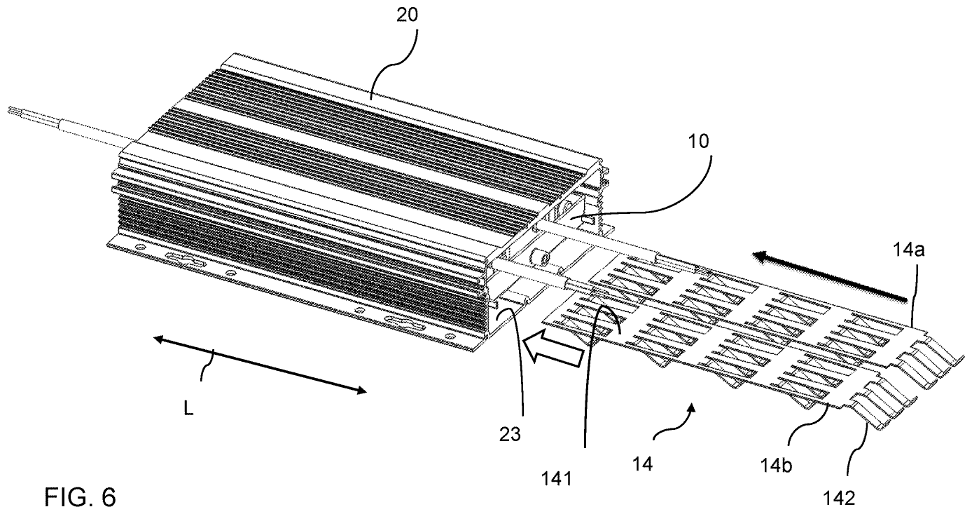

FIG. 6 shows how a set of two equally shaped spring member parts 14a, 14b is placed in front of the one tube opening 22 in order to be inserted into the tube profile 21, or the outer housing part 20, respectively. Both spring member parts 14a, 14b together form the spring member 14. They are each produced from a metal plate (e.g., steel) 141, from which a pattern of spring clips 142 arranged in the form of a matrix is worked out, for example, by punching and bending, in order to bring about the required spring tension and pressure on the support member, afterwards. The spring clips 142 are then bent towards the lower side out of the plane of the metal plate, wherein the free end is bent back in a rounded manner in order to establish a sliding contact.

It is not easy to see in the figures that the spacers 11 are arranged on the underside of the support member 10 in three parallel rows along the longitudinal axis L. As a result, the two spring member parts can each be inserted into the free space between two of the rows of spacers and between the underside of the support member 10 and the lower inner surface 23 of the tube profile, or outer housing part, respectively. The three parallel rows shown along the longitudinal axis L can only be seen as an example. The existing arrangement of 5×6 spring members can also be designed as 4×3 spring members, for example.

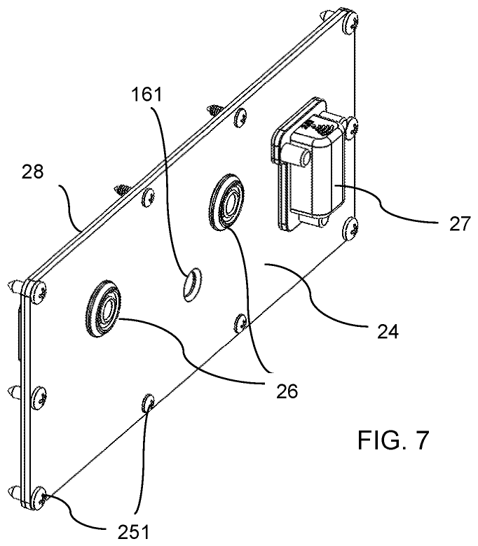

FIG. 7 shows an outer side of a first end plate 24 for closing the tube profile shown in FIG. 6, or one of the two tube openings, respectively. Accordingly, two round cable bushings 26 located at suitable positions are shown in the first end plate 24. Furthermore, a receptacle 27 for an NFC antenna or another wireless contacting possibility of the electronic device 90 is provided. Means for sealing the cable bushings 26 are present. A hole 161 for the pressure compensation and moisture valve is located centrally on the first end plate 24. Furthermore, fastening means 251 (e.g. screws) are shown in FIG. 6, by means of which the first end plate 24 can be fastened to the tube profile. Furthermore, a circumferential sealing ring 28 can be seen, which ensures tightness between the respective end plate 24, 25 and the tube opening 21 in question.

FIG. 8 shows a completely mounted housing including attached end plates 24, 25.

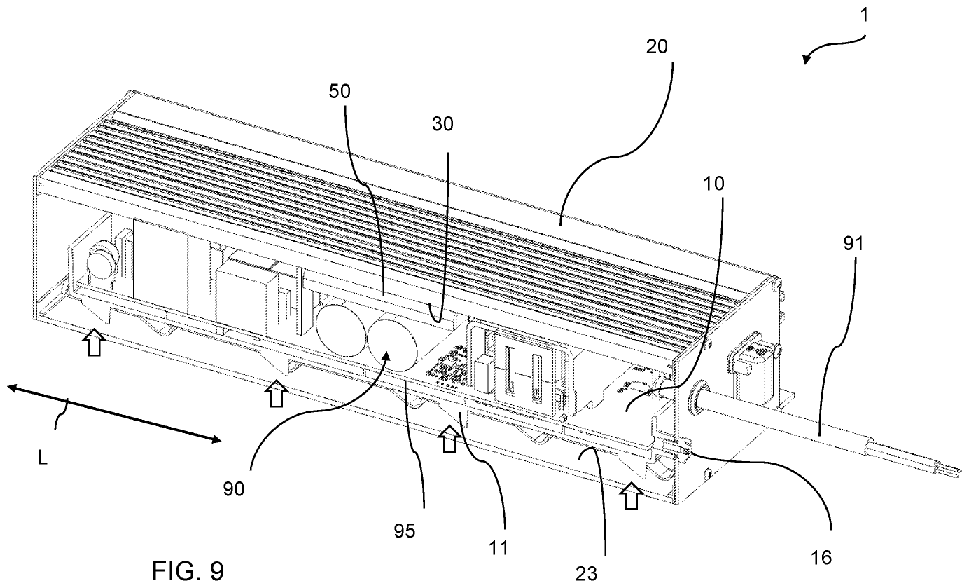

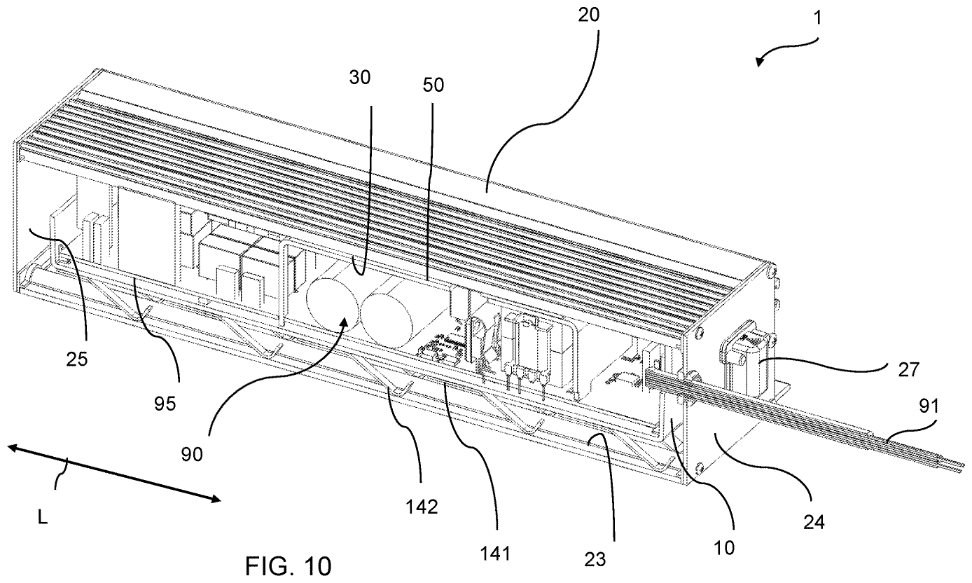

FIGS. 9 and 10 show the effect of the inserted spring element 14 in two different sections along the longitudinal axis L through the assembled housing. The section in FIG. 9 is made in this case to extend exactly through a row of spacers 11 (and rather incidentally also through the pressure compensation and moisture valve 16). As can be seen in FIG. 9 and is indicated by arrows, the support member 10 has been raised by the spring element 14 so that the spacers 11 now no longer touch the lower inner surface 23. The metal plate 141 of the spring element 14 (or the two metal plates) abuts against the underside of the support member 10. Due to the clamping force of the spring clips 142, the metal plate 141 and thus the support member 10 are pressed from the lower inner surface 23 toward the opposite upper inner surface 30. As a result, the thermally conductive contact member or thermal pad 50 is pressed against the upper inner surface 30, so that close contact is established. The thermally conductive paste applied to the thermal pad 50 leads in this case to a safe adhesion and efficient heat transfer to the upper inner surface 30.

The section shown in FIG. 10 extends along a row of spring clips 142, which are each oriented parallel to each other and with their free end in the direction of the tube opening 22 into which the spring member 14 has been inserted so that the spring clips 142 can resiliently retreat upon impact on the front edge of the lower inner surface 23 in the region of the tube opening 22, while the support member 10 is elevated from the underside. The matrix-shaped arrangement of the spring clips 142 well distributed over the metal plate 141 ensures a continuous elevation of the support member 10 from the front to the rear and thus uniform pressure on the printed circuit board 95 arranged above, so that undesired tilting is avoided.

Various modifications of the embodiments mentioned above are possible. For example, the tube profile 21 shown can be turned upside down and the support member 10 can be inserted upright as described. The upper inner surface 30 shown in the figures then becomes the new lower inner surface, and the lower inner surface 23 shown in the figures becomes the new upper inner surface. Analogously to the embodiment of FIGS. 1-10, the spring member 14 can now be inserted or pulled-in under the support member 10 to press the electronic device 90 against the new upper inner surface with the thermal pad 50 interposed and provided with a self-adhesive surface.

Furthermore, FIGS. 1-10 might suggest, but without this being shown, that both the support member and the spring member are inserted in a pushing manner. Just as well, however, in the embodiment, one or the other element, or both, can be pulled into the tube opening concerned from the opposite tube opening by a mechanism not shown.

As described at the outset, the spring member itself may also be modified, for example in that the spring clips are bent out of the plane of the metal plate on both sides in an alternating manner, or that the spring member 14 is simply turned upside down during insertion, so that the free ends of the bent-out spring clips press against the underside of the support member 10 and the metal plate abuts against the lower inner surface.

Furthermore, it was assumed above that the support member 10 with the electronic device 90 thereon itself rests on the lower inner surface before insertion of the spring member 14 (or is held floating above the latter by a lateral intermediate surface not shown). The corresponding force may be gravitational force if the tube profile is aligned in a suitable manner. However, it is just as possible that the force which pushes the support member away from the upper inner surface in this state in order to avoid the contact between the thermal pad and the upper inner surface during the insertion or retraction of the support member is caused by the clamping force of a further spring member. The clamping force of the spring member 14 inserted afterwards then significantly exceeds that of this further spring member.

Furthermore, if there is no concern with regard to the self-adhesive surface of the thermal pad 50, the support member 10 can also be inserted together with the spring member 14. In this case, the two parts can also be formed integrally with one another.

### LIST OF REFERENCE NUMERALS

1 housing

10 support member for electronic device

11 spacer (support member)

12 interior space (support member)

131 opening (edge) of the support member

132 base of the support member

133 lateral outer surfaces of the support member

134 end outer surfaces of the support member

135 lateral inner surfaces (housing part)

14 spring member

141 metal plate

142 spring clip

15 lateral spacers (support member)

16 channel for valve

161 passage for cable bushing

20 outer housing part

21 tube profile

22 end opening in the tube profile

23 lower inner surface

24 first end plate

25 second end plate

251 fastening means for end plate (screws)

26 cable bushings in end plate

27 receptacle for NFC circuit

28 sealing ring (for end plate fastening)

29 fastening flange

30 upper inner surface

40 interior space (housing part)

50 thermally conductive contact member (thermal pad)

90 electronic device

91 electrical cable (output to light sources)

92 electrical cable (power supply)

93 electronic components

95 printed circuit board

L longitudinal axis (outer housing part)

1. A housing for an electronic device, comprising:
an outer housing part,
a support member received in the outer housing part and configured to support the electronic device,
a spring member disposed between the support member and a lower inner surface of the outer housing part and biasing the support member toward an upper inner surface of the outer housing part opposite to the lower inner surface to press the electronic device supported by the support member against the upper inner surface or a thermally conductive contact member interposed between the electronic device and the upper inner surface.

2. The housing according to claim 1, wherein
the outer housing part comprises a hollow tube profile having two tube openings opposite to each other,
wherein the spring member is slidably inserted, or pulled, at the lower inner surface through one of the two tube openings to its predetermined spatial position.

3. The housing according to claim 2, wherein
the hollow tube profile is an extrusion or continuous casting profile, in particular made of aluminum.

4. The housing according to claim 2, wherein
the hollow tube profile has a substantially rectangular cross-section, with integrally formed flanges for fastening to an object.

5. The housing according to claim 2, wherein
the support member has a lower side facing the lower inner surface
wherein at least on the lower side at predetermined positions spacers are configured which, in a state in which the spring member is not yet inserted during assembly of the housing, contact the lower inner surface of the outer housing part in order to allow sliding insertion or retraction of the support member into the hollow tube profile during assembly.

6. The housing according to claim 5, wherein
the spring member comprises a number of spring clips which each extend towards the lower inner surface of the outer housing part, contact the same and, taken together, exert a pressure force distributed over the support member on the support member towards the upper inner surface.

7. The housing according to claim 6, wherein
the spring member comprises a metal plate; which abuts against an underside of the support member and from which the number of spring clips is cut out,
wherein the spring clips are each bent towards one side of a metal plate out of a plane of the metal plate, wherein this side faces the lower inner surface of the outer housing part or the underside of the support member in an inserted or pulled-in state of the spring member,
or wherein the spring clips are each optionally bent towards both sides of the metal plate out of the plane of the metal plate, in particular arranged in an alternating pattern in the metal plate, so that they face both the lower inner surface of the outer housing part and the underside of the support member in an inserted state of the spring member.

8. The housing according to claim 7, wherein
the spring clips are cut out from the metal plate in such a pattern that they have a free end, wherein the spring clips extend substantially parallel to each other and the free end each points in the same direction, wherein the direction points parallel to a longitudinal axis of the housing which extends through both tube openings.

9. The housing according to claim 7, wherein
two or more of the metal plates are provided with the spring clips each,
the spacers are arranged on the underside of the support member in at least two rows which extend parallel to a longitudinal axis of the housing, respectively, and
the metal plates are dimensioned such that they can be inserted between the rows of spacers.

10. The housing according to claim 2, wherein
the support member has a flat trough-like construction with side walls, wherein the side walls also have spacers which face corresponding lateral inner surfaces of the hollow tub profile in an installed state.

11. The housing according to claim 9, wherein
the spacers no longer touch the lower inner surface in an assembled state because the spring element pushes the support member away from the lower inner surface.

12. The housing according to claim 2, further comprising:
two end plates opposite to each other and attached at end faces to the two tube openings, which end plates close off an interior space of the outer housing part, wherein at least one of the end plates has sealing cable bushings for electrical cables.

13. The housing according to claim 2, wherein
the thermally conductive contact member is a thermal pad, wherein the thermal pad is self-adhesive on at least one side, to be fixed to the upper inner surface of the outer housing part and to an at least partially planar and thermally conductive member of the electronic device.

14. The housing according to claim 2, wherein
an interior space formed by the outer housing part is free of potting compound otherwise filled into the interior space, in particular free of silicone, epoxy resin or tar.

15. A method for producing a housing comprising:
providing an outer housing part formed as a hollow tube profile having two tube openings opposite to each other;
slidably inserting or retracting a support member, on a lower inner surface of the outer housing part, wherein the support member supports an electronic device arranged on an upper side thereof, into the hollow tube profile via one of the two tube openings, so that the electronic device is opposite to an upper inner surface of the outer housing part;
slidably inserting or retracting a spring member on the lower inner surface and below a lower side of the support member opposite to the upper side, through one of the two tube openings, so that the spring member biases the support member toward the upper inner surface of the outer housing part to press the electronic device supported by the support member against the upper inner surface or a thermally conductive contact member interposed between the electronic device and the upper inner surface.

16. The housing according to claim 2, wherein the housing also comprises the electronic device, so that the housing together with the electronic device forms an electronic apparatus, wherein the electronic device comprises a printed circuit board with electronic components attached thereto;
wherein the electronic device is an electronic ballast for semiconductor light sources, with a power consumption of 500 watts or more.
